(19) United States
(12) Patent Application Publication
(10) Pub. No.: US 2011/0308562 A1
(43) Pub. Date: Dec. 22, 2011

(54) PHOTOVOLTAIC MODULE ELECTRICAL CONNECTORS

(75) Inventor: Paul Shufflebotham, San Jose, CA (US)

(73) Assignee: MIASOLE, Santa Clara, CA (US)

(21) Appl. No.: 12/820,408

(22) Filed: Jun. 22, 2010

(51) Int. Cl. H01L 31/042; H01L 31/00

(52) U.S. Cl. 136/244; 136/256

(57) ABSTRACT

Provided are novel photovoltaic module electrical connectors, photovoltaic assemblies including these connectors, and techniques for installing these connectors to sealed photovoltaic modules. According to various embodiments, the connectors have conductive contact tips that are configured to pierce through a module exterior and form an electrical connection to the photovoltaic cells sealed inside. In certain embodiments, the novel photovoltaic module electrical connectors can be positioned at any location along one or more edges of a module to establish an electrical connection to any cell of the module. The conductive contact tips establish mechanical contacts with contact layers inside the modules, and in certain embodiments partially or completely penetrate the contact layers, without shorting the photovoltaic cells. In certain embodiments, the connectors have positive stop features that control penetration distances of the conductive contact tips into a module.

### BACKGROUND

Photovoltaic technology is being rapidly adopted for generating electrical power from sun light using the photovoltaic effect. Photovoltaic cells, which are often also referred to as solar cells, are basic elements of photovoltaic systems. Each photovoltaic cell includes a semiconductor stack (e.g., a p-n junction) that is configured to generate a voltage when the stack is exposed to sun light. One or more photovoltaic cells are typically integrated into a photovoltaic module, often referred to as a photovoltaic panel. solar panel, or solar module. Photovoltaic modules may in turn be interconnected in a photovoltaic array. Each of these integration levels involves multiple electrical interconnections.

A conventional photovoltaic module has a set of photovoltaic cells interconnected in series and two module connectors. These connectors are installed during fabrication of the module, positioned in predetermined locations (e.g., near two module corners), and electrically connected to the cells of the interconnected set. These module connectors are then used to connect the module to additional circuit elements during installation of the module in an array. Multiple operations during fabrication and installation and multiple components including module connectors and additional circuit elements are needed to establish an electrical connection to each module. This complexity adds to the overall costs of photovoltaic systems. The pre-installed module connectors can be used to provide power at only one specified voltage. Any voltage adjustments require voltage converters.

### SUMMARY

Provided are novel photovoltaic module electrical connectors, photovoltaic assemblies including these connectors, and techniques for installing these connectors to sealed photovoltaic modules. According to various embodiments, the connectors have conductive contact tips that are configured to pierce through a module exterior and form an electrical connection to the photovoltaic cells sealed inside. In certain embodiments, the novel photovoltaic module electrical connectors can be positioned at any location along one or more edges of a module to establish an electrical connection to any cell of the module. The conductive contact tips establish mechanical contacts with contact layers inside the modules, and in certain embodiments partially or completely penetrate the contact layers, without shorting the photovoltaic cells. In certain embodiments, the connectors have positive stop features that control penetration distances of the conductive contact tips into a module.

In certain embodiments, a photovoltaic assembly includes a photovoltaic module and photovoltaic module electrical connector. The module includes a semiconductor junction and a contact layer, which are sealed between a first sheet and a second sheet. The first sheet is made of a pierceable material. The photovoltaic module electrical connector includes a contact arm that has a conductive contact tip for penetrating the first sheet of the module to contact the contact layer. Furthermore, the photovoltaic module electrical connector may include a support arm that forms a variable gap with the contact tip. The photovoltaic module electrical connector also includes an insulator that surrounds at least a portion of the contact arm and/or support arm and provides electrical insulation to that portion. The support and contact arms may be configured to maintain the variable gap at a distance or range of distances such that the contact tip maintains an electrical contact to the contact layer but does not penetrate completely through the contact layer. In certain embodiments, the photovoltaic module electrical connector is provided by itself, i.e., without being necessarily connected to or otherwise combined with a photovoltaic module. In certain embodiments, a photovoltaic module or set of modules may be provided with one or more connectors as part of an installation kit. In other embodiments, connectors configured to connect to a certain type of module or modules may be provided alone.

The photovoltaic module electrical connector may include a positive stop that is configured to maintain a variable gap such that the contact tip maintains an electrical contact to the contact layer but does not penetrate completely through the contact layer. A positive stop may be provided by a direct contact between the contact arm and the support arm. In other embodiments, a positive stop includes a surface contacting the first sheet of the photovoltaic module such that the contact tip extends from that surface by a predetermined distance. In certain embodiments, the variable gap is maintained at a distance sufficiently large to accommodate at least the semiconductor junction and the second sheet without causing an electrical short to the junction. The variable gap may be maintained, for example, by a set force. In certain embodiments, the set force is controlled by a mechanical spring provided between the contact arm and the support arm. The set force may be adjustable.

In certain embodiments, a photovoltaic module includes a reinforcement strip positioned between the semiconductor junction and the contact tip. In the same or other embodiments, the contact tip is bent relative to a penetration direction. The contact tip may partially penetrate the contact layer without causing an electrical short in the photovoltaic stack. The contact tip may be sufficiently conductive to transmit an electrical current provided by at least five photovoltaic modules interconnected in parallel. In certain embodiments, the photovoltaic module electrical connector includes a plurality of contact tips.

In certain embodiments, a first sheet has an average thickness between about 5 mils and 100 mils. The first sheet may be a backside sheet including a metallic vapor barrier. In such cases, the contact tip may have an insulating sheath covering a portion of its side wall, insulating it from the metallic vapor barrier. The contact layer may include one or more layers of a stainless steel substrate used for mechanical support of the photovoltaic stack, a set of metallic current-collector wires positioned over a frontside of the photovoltaic stack, a tab extending outside of the photovoltaic stack, a bus bar electrically connected to the photovoltaic stack, or other conductive materials, layers, and/or structures electrically connected to the photovoltaic stack.

In certain embodiments, a contact tip is self-sealing such that when it penetrates the first sheet, it seals the photovoltaic module from an external environment in a penetration area. A photovoltaic module electrical connector may include a sealing material compressed between the contact arm and the first sheet. In certain embodiments, the contact tip includes one or more retaining features configured to maintain the electrical contact between the conductive contact tip and the contact layer.

In certain embodiments, a photovoltaic assembly is configured such that a photovoltaic module electrical connector can be installed at any location along an edge of the photovoltaic module. The photovoltaic assembly may include a second photovoltaic module electrical connector for connecting to a second photovoltaic stack and a third photovoltaic module electrical connector for connecting to a third photovoltaic stack of the photovoltaic module. The three stacks are electrically interconnected in series and connected to their respective photovoltaic module electrical connectors. A voltage between the first connector and the second connector and a voltage between the second connector and the third connector may be substantially the same.

Another aspect of the invention relates to photovoltaic arrays including electrically connected modules. In certain embodiments, the photovoltaic array includes at least one photovoltaic module including a plurality of interconnected photovoltaic cells sealed within an exterior; at least two external connectors electrically connected to different cells of the plurality of photovoltaic cells; wherein the at least two external connector comprise conductive contact tips pierced through the exterior of the photovoltaic module.

These and other aspects of the invention are described further below with reference to the figures.

### BRIEF DESCRIPTION OF THE DRAWINGS

FIG. 1A is a schematic representation of a photovoltaic cell in accordance with certain embodiments.

FIG. 1B is a schematic representation of a photovoltaic assembly that includes a photovoltaic module and an installed electrical connector in accordance with certain embodiments.

FIG. 1C is a schematic representation of a photovoltaic assembly that includes a photovoltaic cell, a network of current collector wires, and an installed electrical connector with multiple contact tips in accordance with certain embodiments.

FIG. 1D is a schematic representation of a photovoltaic assembly illustrating a force control feature positioned between a contact arm and a support arm in accordance with certain embodiments.

FIG. 1E is a schematic representation of a photovoltaic assembly illustrating an example of a contact tip having retaining features.

FIG. 1F is a schematic representation of a photovoltaic subassembly illustrating multiple contact tips establishing a contact with a current collector in accordance with certain embodiments.

FIG. 2A is a schematic representation of a photovoltaic assembly illustrating a contact arm extension and a support arm extension forming a positive stop in accordance with certain embodiments.

FIG. 2B is a schematic representation of a photovoltaic assembly illustrating a positive stop feature positioned between a contact arm and a sealing sheet in accordance with certain embodiments.

FIG. 3A is a schematic representation of a contact arm having a bendable contact tip during penetration of a sealing sheet prior to reaching the contact layer of the photovoltaic stack in accordance with certain embodiments.

FIG. 3B is a schematic representation of the contact arm shown in FIG. 3A, with a bent contact tip after reaching the contact layer in accordance with certain embodiments

FIG. 4A is a schematic representation of a photovoltaic assembly illustrating a contact tip having an insulating sheath in accordance with certain embodiments.

FIG. 4B is a schematic representation of a photovoltaic assembly illustrating a U-channel formed by the module connector around the edge of the photovoltaic module in accordance with certain embodiments.

FIG. 5 is a schematic representation of a photovoltaic module having three electrical, connectors connected to different photovoltaic stacks of the module in accordance with different embodiments.

FIG. 6 is a process flowchart corresponding to one example of a technique for installing an electrical connector to a photovoltaic module.

FIG. 7 is a schematic representation of a photovoltaic array containing multiple photovoltaic modules and electrical connectors in accordance with certain embodiments.

### DETAILED DESCRIPTION OF EXAMPLE EMBODIMENTS

In the following description, numerous specific details are set forth in order to provide a thorough understanding of the present invention. The present invention may be practiced without some or all of these specific details. In other instances, well known process operations have not been described in detail to not unnecessarily obscure the present invention. While the invention will be described in conjunction with the specific embodiments, it will be understood that it is not intended to limit the invention to the embodiments.

### Introduction

The novel photovoltaic module electrical connectors described herein are designed to establish electrical connections to sealed photovoltaic modules. In certain embodiments, the module connectors include conductive contact tips that are used to pierce through one of the sealing sheets of the photovoltaic modules and to form electrical connections to contact layers sealed inside the modules. The connectors allow post-fabrication connection to the sealed cells without shorting any semiconductor junctions of the cells and without compromising the module seals during installation or during later operation. In certain embodiments, the module connectors have two arms: a contact arm carrying the tip and a support arm. During installation, the connector can be positioned over a module edge such that the arms extend over opposing sides of the module. The two arms are then pressed towards each other causing the tip to pierce through the sealing sheet and to reach the contact layer. A positive stop or a force control mechanism may then be used to control how deep the tip penetrates into the module.

Photovoltaic systems that use these novel connectors are cheaper to fabricate and install. In certain embodiments, they eliminate the need to install connectors during module fabrication. Photovoltaic modules without pre-installed connectors are less expensive to make, easier to transport, and are less prone to develop connection defects prior to installation of modules in an array. Furthermore, the novel module connectors can be integrated with other circuit components to substantially reduce installation complexity. In certain embodiments, a connector can be installed at any location along one or more edges of a module. This allows building photovoltaic assemblies having different voltage outputs without a need for additional voltage converters.

### Examples of Electrical Connectors and Photovoltaic Assemblies

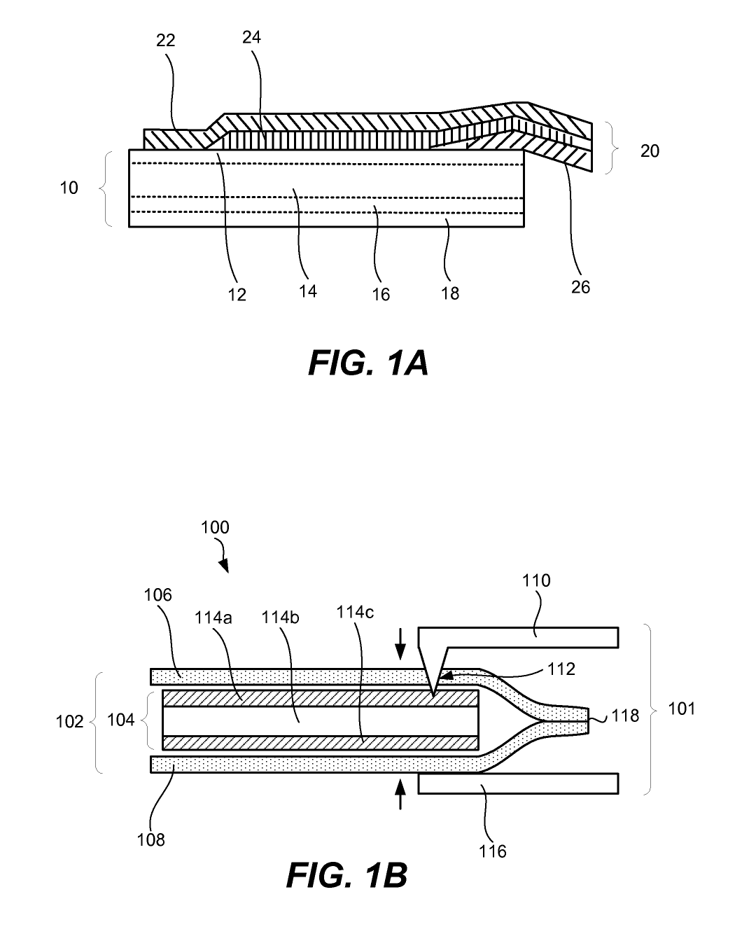

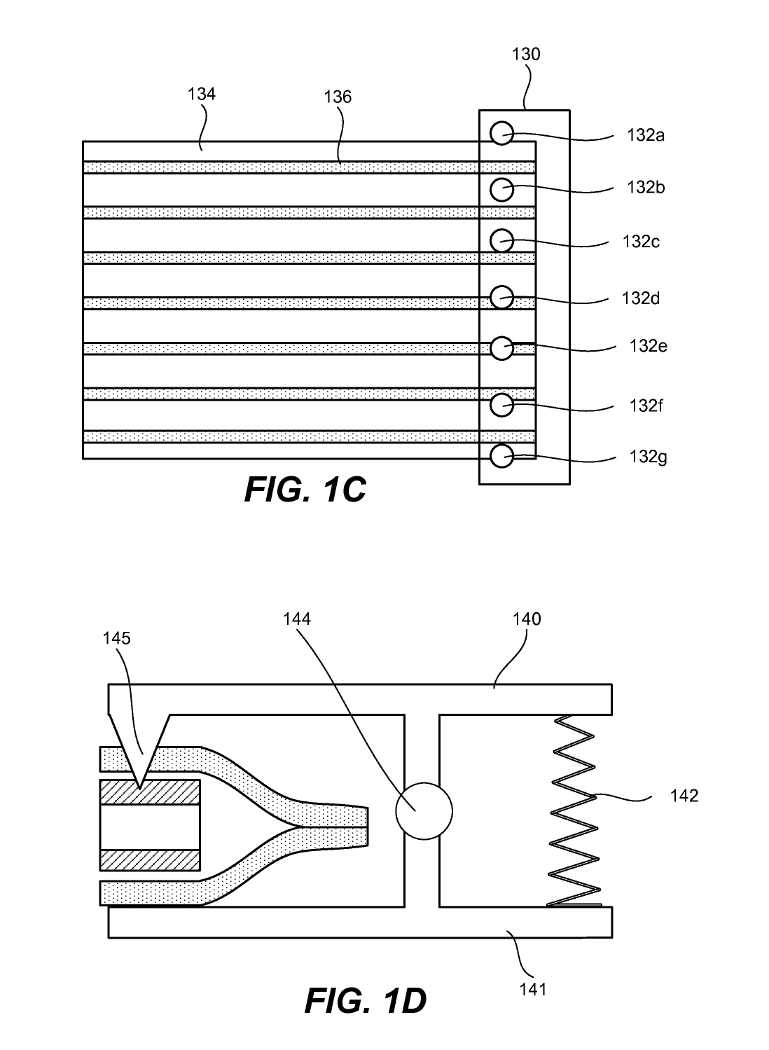

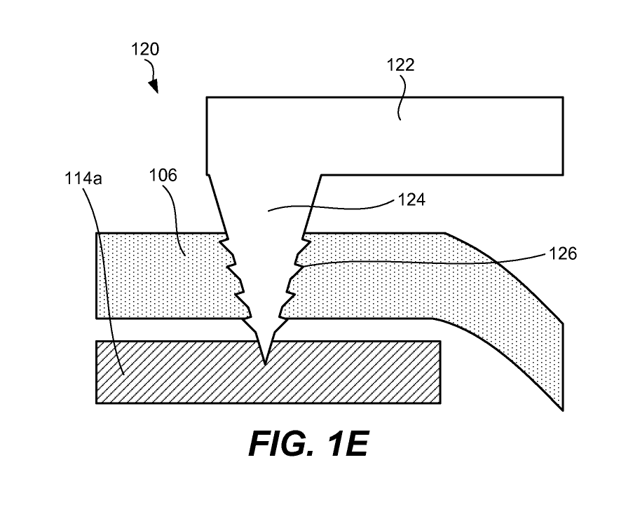

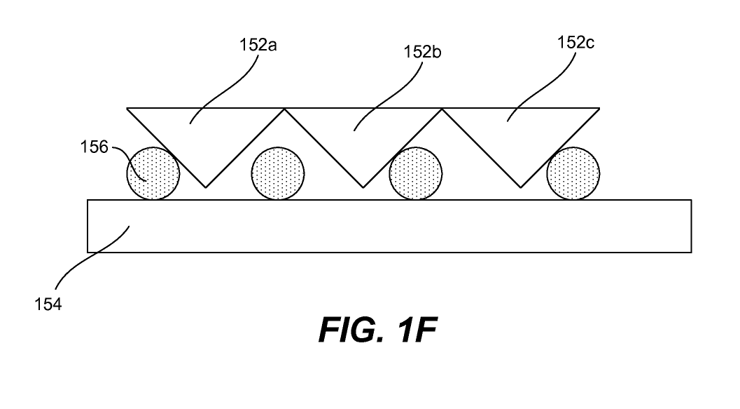

To provide a better understanding of various features of the novel photovoltaic module electrical connectors, a brief description of a photovoltaic cell and a current collector assembly is presented. It should be understood that module connectors can be installed on different kinds of photovoltaic modules that include this and/or other types of photovoltaic cells. FIG. 1A is a schematic representation of a photovoltaic cell 10 and a portion of a current collector 20 in accordance with certain embodiments. The photovoltaic cell 10 includes a semiconductor junction 14. The semiconductor junction 14 may include copper indium gallium selenide (CIGS) or other materials further described below. The semiconductor junction 14 is configured to generate a voltage when exposed to sun light. A typical thickness of a CIGS junction is between about 500 nanometers to 3000 nanometers, for example, between about 1500 nanometers and 2000 nanometers. According to various embodiments, the thicknesses of semiconductor junctions may be within or outside these ranges, depending on the type of junction employed.

The semiconductor junction 14 may be positioned adjacent to a back conductive layer 16, which, in certain embodiments, is a thin layer of molybdenum, niobium, copper, and/or silver. The photovoltaic cell 10 may also include a substrate 18, which may be used for mechanical support of the semiconductor junction 14 and other layers. In certain embodiments, the substrate is a conductive material such as a metal or conductive polymer. Examples of metallic substrates include stainless steel foil, titanium foil, copper foil, aluminum foil and beryllium foil. In certain embodiments, the substrates are between about 2 mils and 50 mils thick, e.g., about 10 mils thick, with other thicknesses also in the scope of the invention. The cell 10 may also include a top conductive layer 12. This layer typically includes one or more transparent conductive oxides (TCO), such as zinc oxide, aluminum-doped zinc oxide (AZO), indium tin oxide (ITO), and gallium doped zinc oxide. A typical thickness of a TCO layer is between about 100 nanometers to 1000 nanometers, for example between about 200 nanometers and 800 nanometers, with other thicknesses within the scope of the invention. A combination of the top conductive layer 12, the semiconductor junction 14, and the back conductive layer 16 is often referred to as a photovoltaic stack.

As used herein, the term “contact layer” refers to a layer electrically connected to the semiconductor junction that is sealed within the module and physically contacted by a contact tip of a module connector, or to which a contact tip is configured to physically contact. Any one of the layers 12, 16, or 18 of the cell 10 or various combinations of these layers may serve as a contact layer that forms an electrical connection with an installed module collector. For example, an installed module connector can contact the metallic substrate 18 and/or the back conductive layer 16.

In certain embodiments, the contact layer is or includes a current collector, cell-to-cell interconnect, bus wire or other electrical component that is electrically coupled to a photovoltaic cell. In FIG. 1A, the photovoltaic cell 10 is coupled to a current collector 20 that collects current from top conductive layer 12 and provides, for example, an electrical connection to an adjacent cell (not shown) connected in series with the cell 10. The current collector 20 includes a conductive component 24 (e.g., an electrical trace or wire) that contacts the top conductive layer 12 (e.g., a TCO layer) of the cell 10. The current collector 20 may further include a top carrier film 22 and/or a bottom carrier film 26, which may be made from insulating materials to prevent electrical shorts.

Interconnected cells, such as cell 10 in FIG. 1A, are sealed within a module. The module exterior typically includes one or more sheets of a weatherable material that prevent moisture ingress and protect the cells from environmental conditions. A top sealing sheet, i.e., a sealing sheet that overlays the TCO layer, is a transparent material that allows light transmission to the semiconductor junction. The module is typically planar, having top and bottom major faces. In many cases, a top sealing sheet is sealed around the module periphery to a bottom sealing sheet. The top and bottom sealing sheets are referred to herein interchangeably as first and second sealing sheets. First and second sealing sheets more generically refer to a module exterior of a front (light facing) and a back side of the module.

Various examples of photovoltaic module electrical connectors will be now described in more detail with reference to photovoltaic assemblies. FIG. 1B is a schematic representation of a photovoltaic assembly 100 that includes a photovoltaic module 102 and an installed electrical connector 101 in accordance with certain embodiments. The module 102 includes a photovoltaic cell 104 with a semiconductor junction 114b. This junction 114b generates a voltage when exposed to sun light and applies this voltage to two layers 114a and 114c that may be also a part of the cell 104. Either or both of these layers 114a and 114c may be a contact layer as described above with reference to FIG. 1A. For example, the layer 114a may represent a metallic substrate and/or layer 114c may represent a wire current collector, or vice versa. The cell 104 is sealed between two sealing sheets 106 and 108, at least one of which is pierceable by a conductive contact tip of the electrical connector 101. In the example shown in FIG. 1B, layer 114a is a contact layer. Specifically, FIG. 1B illustrates the sheet 106 pierced through by the tip 112, which contacts the layer 114a and establishes an electrical connection to it. Generally, photovoltaic cells with any type of semiconductor junctions can be used. Some examples include cadmium-telluride (Cd—Te) cells, copper-indium-gallium-selenide (CIGS) cells, amorphous silicon (a-Si) cells, micro-crystalline silicon, and crystalline silicon (c-Si) cells.

In certain embodiments (such as that shown in FIG. 1B), the contact tip 112 establishes an electrical connection with the contact layer 114a over the semiconductor junction 114b. In these embodiments, there is some risk of an electrical short if the penetration distance of the tip is not properly controlled. While the tip may generally penetrate through at least a portion of the contact layer 114a, it does not pierce completely through the layer 114a. In other embodiments further described below, the contact tip 112 may penetrate through a portion of the junction 114b or even pierce completely through the junction 114b without shorting it.

In certain embodiments, a contact layer is or extends outside of the junction's lateral boundaries such that the contact point between the contact layer and the contact tip does not overlie or underlie the semiconductor junction. For example, a contact layer may be or have a tab laterally extending away from a junction and, for example, towards an edge of the module. In another example, a metallic substrate, wire current collector, or other conductive layer that overlies or underlies the semiconductor junction may extend laterally past the junction. Electrical connections between contact tips and contact layers are made in these extended areas. A tip may pierce completely through a contact layer in an extended area without a risk of damaging the junction. It should be noted that this configuration allows connection to two contact layers through the same pierceable sheet. For example, a photovoltaic module may include a tabbed contact layer extending from a top current collector of one cell in the module and another one extending from a bottom current collector of another cell in the module. Two connectors or a single connector having two contact tips can pierce through the same sealing sheet in order to establish electrical connections to the two extensions. In another embodiment, a photovoltaic module includes a tabbed contact layer extending away from the cell periphery and connected to one side of the semiconductor junction. A module connector can then be connected to this extension. The same or another module connector can connect to another contact layer of the module in a manner similar to the one described in the context of FIG. 1B. In this embodiment, both electrical connections can be still made through the same sealing sheet.

Returning to FIG. 1B, in certain embodiments, the electrical connector 101 has a contact arm 110 and a support arm 116. The contact arm 110 carries a contact tip 112 and points it towards the photovoltaic module 102 during installation. The contact arm 110 extends over one side of the module 102. The support arm 116 may be configured to extend on the other side of the module 102. The support arm 116 and the contact arm can together exert a force onto the module 102. In certain embodiments, the force is controlled during installation of the connector 101 and/or during operation of the assembly, as described further below.

The photovoltaic module 102 includes at least one sheet that can be pierced through with the contact tip 112, e.g., the sheet 106 in FIG. 1B. Such a sheet or sheets are referred to herein as a “pierceable” sheet or sheets. A pierceable sheet can be made from polyethylene, polyethylene terephthalate (PET), polypropylene, polybutylene, polybutylene terephthalate (PBT), polyphenylene oxide (PPO), polyphenylene sulfide (PPS) polystyrene, polycarbonates (PC), ethylene-vinyl acetate (EVA), fluoropolymers (e.g., polyvinyl fluoride (PVF), polyvinylidene fluoride (PVDF), ethylene-terafluoethylene (ETFE), fluorinated ethylene-propylene (FEP), perfluoroalkoxy (PFA) and polychlorotrifluoroethane (PCTFE)), acrylics (e.g., poly(methyl methacrylate)), silicones (e.g., silicone polyesters), and/or polyvinyl chloride (PVC), as well as multilayer laminates and co-extrusions. A typical thickness of a pierceable sheet is between about 5 mils and 100 mils or, more specifically, between about 10 mils and 50 mils.

A photovoltaic module may include other components that are not specifically illustrated in FIG. 1B. For example, the module may have one or more encapsulant layers provided between a sealing sheet and a contact layer. The encapsulant may help seal the area where the contact tip pierces through a sheet. Examples of encapsulant materials include non-olefin thermoplastic polymers or thermal polymer olefin (TPO), such as polyethylene (e.g., a linear low density polyethylene, polypropylene, polybutylene, polyethylene terephthalate (PET), polybutylene terephthalate (PBT), polystyrene, polycarbonates, fluoropolymers, acrylics, ionomers, silicones, and combinations thereof.

The conductive contact tip 112 of the electrical connector 110 is configured to pierce through at least a sealing sheet and to establish and maintain an electrical connection with the contact layer 114a. In certain embodiments, the tip 112 has a “needle”-like or “nail”-like shape. Such shapes allow the tip 112 to easily pierce through the sheet 106 and to seal, at least partially, the piercing area.

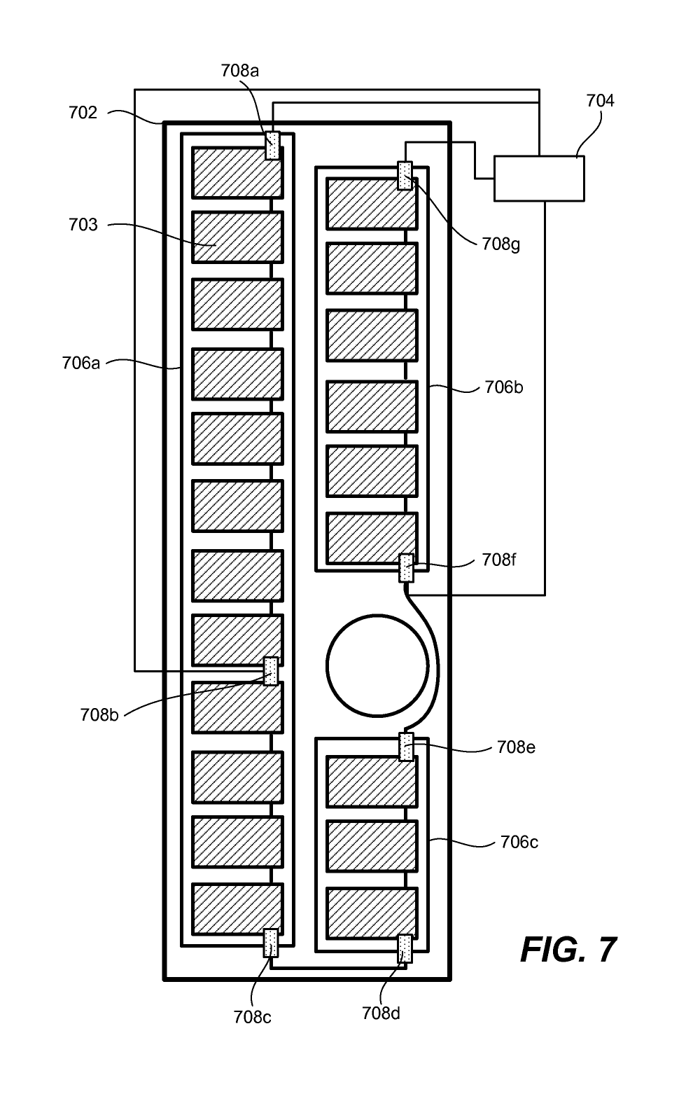

The tip 112 includes at least some conductive material that provides an electrical current pathway from the tip to another connection element of the connector (e.g., a wire or a socket). In certain embodiments, this current pathway is sufficient to pass an electrical current produced by at least two modules or, by at least five modules or by at least ten modules interconnected in parallel. Examples of module arrangements are further described in the context of FIG. 7 and in U.S. patent application Ser. No. ______, titled “Flexible Photovoltaic Modules in a Continuous Roll,” (Attorney Docket MSOLP040, filed concurrently) incorporated herein by reference. At the same time, the tip 112 should be sufficiently rigid to withstand applied mechanical forces during installation of the electrical connector 101, or more specifically during piercing of the sealing sheet with the tip 112. Examples of the contact tip materials include copper, aluminum, titanium, steel, and combinations of thereof.

In certain embodiments, a module connector includes multiple contact tips. This configuration may be useful for conducting high electrical currents and/or for establishing an electrical connection to topographically uneven surfaces. As described above, some contact layers include networks of current collector wires. Such networks may have spacing in between the wires to allow light transmission to semiconductor junctions positioned under these networks. In certain embodiments, a connector with multiple tips is configured such that at least one tip makes an electrical connection with at least one wire of the network. FIG. 1C is a schematic representation of a photovoltaic cell 134 with a network of current collector wires 136 and an installed electrical connector 130 with multiple contact tips 132a-132g. As shown, at least three contacts tips, 132d-132f makes electrical contacts with the current collectors 136. FIG. 1F shows a cross-sectional view of another embodiment of a connector having multiple tips 152a-152c in contact with a wire network 156 overlying a TCO layer 154. A cross-section of the wire network 156 is shown. In the depicted embodiment, the contact tips are configured such that at least one tip makes contact with the wire network 156, and that this contact prevents the tips 152a-152c from further penetrating and contacting, for example, the TCO layer 154.

According to various embodiments, structural and/or functional features of the module connector and/or module control a penetration distance of a contact tip into a photovoltaic module. As noted above, the tip penetrates far enough to establish physical contact to and an electrical connection with the contact layer. At the same time, the penetration distance should not cause an electrical short or otherwise damage the semiconductor junction. In certain embodiment, the penetration distance is such that the tip does not contact other layers of the photovoltaic stack such as the TCO layer (as shown in FIG. 1F) or the back conductive layer. While in certain embodiments the TCO layer or the back conductive layer can serve as a contact layer, in other embodiments it may be desirable to prevent a physical contact between the contact tip and these layers, e.g., due to their relatively small thicknesses.

In certain embodiments, a module connector is configured to apply a controlled force to a photovoltaic module to control a penetration distance. During installation, the applied force is sufficiently large that the contact tip pierces through the sealing sheet of the module. The sealing sheet and/or other elements (e.g., a contact layer) may provide sufficient resistance to this force and in this way control the penetration distance. In certain embodiments, a module includes a reinforcement element to stop the contact tip from penetrating further. For example, a narrow metal strip may be integrated into a contact layer to reinforce the layer in at least in the contact area. A reinforcement strip may be between about 0.125 inches and 1 inch wide or, more particularly, between about 0.25 inches and 0.5 inches wide.

In the same or other embodiments, a module connector may be configured to apply variable forces to the module depending on the gap between the two arms of the connector. In certain embodiments, a connector includes a mechanical spring that provides a variable force at different compression levels. FIG. 1D illustrates a module connector with two arms 140 and 141 and a spring 142 in accordance with certain embodiments. The spring 142 is configured to force the arms away from each other at the location of the spring 142. The module connector has a pivoting mechanism 144 that translates this force into a force that pushes the contact tip 145 into the module. Controlling the spring force in turn controls the force applied by the tip 145 onto the module. A connector may allow changing springs and/or adjusting forces or pre-loading the spring 142 depending on particular requirements of different photovoltaic modules and/or contact tip configurations. For example, thicker sealing sheets and/or larger contact tips may require more force during installation. In some embodiments, an installer may apply an additional force during installation until a contact tip reaches its operating position and then rely on a force provided by the electrical connector to maintain the tip at the installed position. For example, an installer may press on the contact arm until it forced against a positive stop (described further below) at which point a retaining feature holds the top in contact with the contact layer.

In certain embodiments, a photovoltaic module electrical connector has only one connector arm. For example, a connector may have a contact arm that extends over the pierced side of the module with no arm or elements extending over the other side of the module during or after installation. In these embodiments, the connector may have various features to maintain an electrical connection between the conductive contact tip and contact layer. FIG. 1E is a schematic representation of a photovoltaic assembly 120 illustrating one example of retaining features 126 positioned on the contact tip 124, which contacts and is electrically connected to contact layer 114a. Similar to the previously described embodiments, the contact tip 124 is carried on the contact arm 122. The retaining features 126 interlock with the pierced sheet 106 and prevent the contact tip 124 from sliding out of its installed position and losing its electrical connection with the contact layer 114a. According to various embodiments, retaining features are a set of ribs (e.g., as shown in FIG. 1E) or indents provided on the sides of the contact tip, and/or an adhesive positioned between the contact arm and the first sheet. Retaining features may be provided on components other than the contact tip. For example, the connector may include one or more extensions that partially penetrate the sealing sheet and do not establish an electrical connection.

In certain embodiments, a position of the contact tip relative to other assembly components may be defined by a variable gap, which for the purposes of this document is a distance between the contact tip and the surface defined by the support arm portions configured to contact the second sealing sheet, i.e., the sheet that is not pierced through by the tip. During installation, the variable gap is initially greater than the overall module thickness in order to slide the connector over the module edge. The variable gap is then reduced to bring the support arm in contact with the second sheet and initiate piercing of the first sheet and, eventually, to form an electrical connection with a contact layer sealed inside the module. It should be noted that after the installation, the variable gap needs to accommodate at least the thicknesses of the second sheet and the semiconductor junction. While some penetration of the tip into the contact layer may be permissible, e.g., to lower a contact resistance between the tip and the contact layer, the junction should not be shorted by the tip.

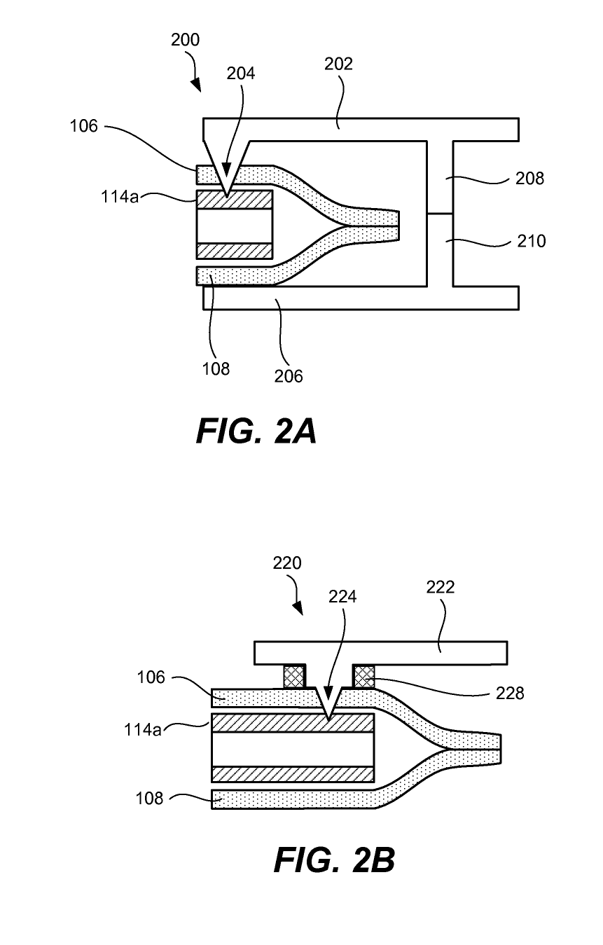

In certain embodiments, a photovoltaic assembly includes a positive stop that limits how far the contact tip can penetrate into the module. FIG. 2A is a schematic representation of a photovoltaic assembly 200 illustrating a contact arm extension 208 and a support arm extension 210 that form a positive stop after installation in accordance with certain embodiments. Prior to and during the initial stages of the connector installation, the two arms are spaced further apart such that the two extensions 208 and 210 are separated. This provides enough distance between the contact tip 204 and the support arm 206 to slide the connector over the edge of the module. Then the contact arm 202 is advanced towards the support arm 206, and at some point the contact tip 204 starts piercing through the sealing sheet 106 and eventually establishes an electrical connection with the contact layer 114a. The arm extensions 208 and 210 then come into contact with each other and stop further advancement of the tip 204 into the module. The extensions 208 and 210 are configured in such a way that the tip advances far enough into the module to form an electrical connection with the contact layer but is stopped before shorting the semiconductor junction.

In another configuration, an outside surface of the pierced sealing sheet can be used as a reference plane for controlling the penetration distance of the contact tip. One such example is shown in FIG. 2B. A positive stop feature 228 is positioned between the connector arm 222 and the sealing sheet 106. This feature 228 can be a separate element (e.g., a spacer washer that slides over the contact tip), a part of the contact arm 222, and/or a part of the module (e.g., a control bump on the sealing sheet). The feature 228 may also be removable. For example, the same connector can be used for different types of modules, e.g., modules with different sealing sheet thicknesses. A specific spacer is then provided for each module type, e.g., thinner spacers for modules with the thicker sheets and vice versa. When both the connector arm 222 and the sealing sheet 106 come into contact with the positive stop feature 228 as shown in FIG. 2B, further advancement of the contact tip into the module is prevented by the positive stop.

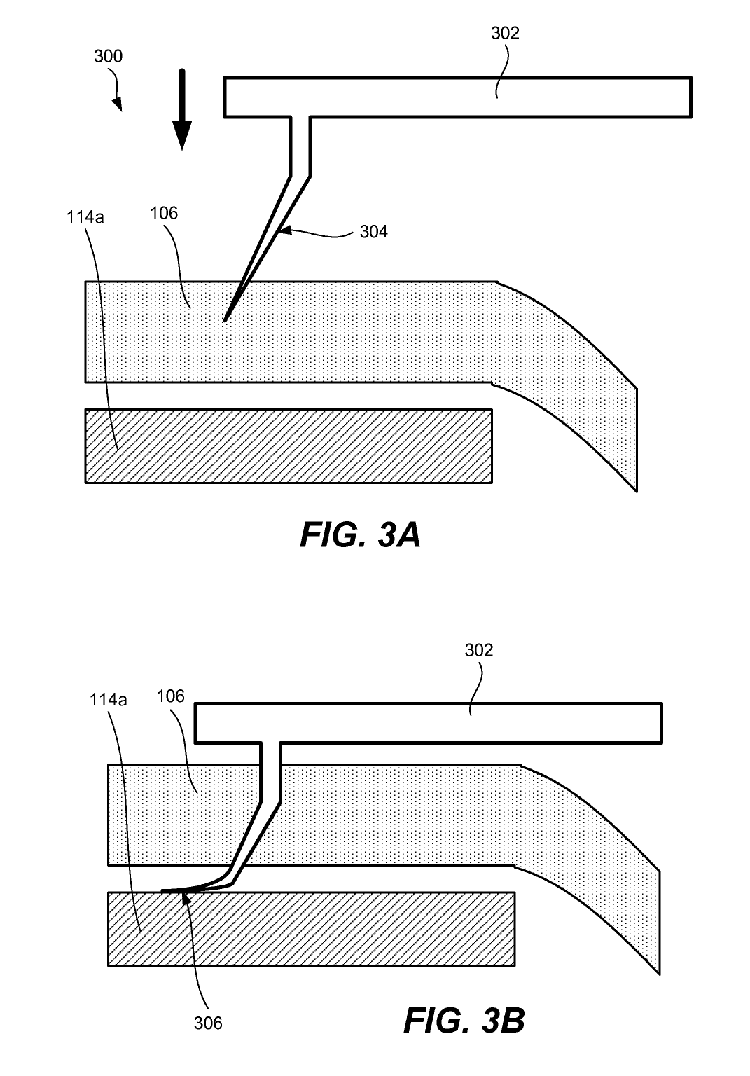

In certain embodiments, a contact tip is sufficiently flexible that it bends when forced again a contact layer. FIGS. 3A and 3B provide schematic representations of a photovoltaic assembly 300 with a contact arm 302 including a bendable contact tip 304 during the installation of the connector and after the installation. In FIG. 3A, the contact tip is shown during penetration of the first sheet 106 and prior to reaching the contact layer 114a. When the contact tip 304 is pushed further, it hits the contact layer 114a. In certain embodiments, the contact layer 114a is substantially harder than the first sheet 106 and this further advancement causes the tip to bend. The tip may also be specifically configured to facilitate this bending. For example, a tip may be advanced at an oblique angle relative to the surface of the contact layer 114a, as in the example shown in FIG. 3A. In certain embodiments, a tip is initially fed through a sleeve while it pierces through the sealing sheet, but extends outside of the sleeve when it approaches the contact layer. The sleeve prevents premature bending, e.g., when the tip is pushed through the sealing sheet. The sleeve may be pushed through the sealing sheet prior to or with the contact tip. In certain embodiments, it is provided as a removable or non-removable part of the connector. FIG. 3B illustrates an example of the bent tip 306 after the installation of the connector is completed.

Generally, a photovoltaic module remains sealed after its sealing sheet is pierced through with a contact tip. In certain embodiments, advancement of the tip into the sealing sheet creates sufficient pressure between the tip and the sealing sheet to form a seal around the tip. In the same or other embodiments, various additional sealing features are used. For example, a sealing ring or sealing materials may be positioned around the contact tip prior to installation of the connector onto a module. Pushing the tip into the sheet pushes the sealing ring or sealing materials against the sealing sheet surface to form a seal in the penetration area. In other embodiments, a sealing feature may be added after the connector reaches it final position. For example, a sealing material may be distributed around the penetration area after the installation of the connector. Examples of sealing materials include various organic or inorganic materials that have a low inherent water vapor transmission rate (WVTR) (typically less than 1-2 g/m²/day) and, in certain embodiments may absorb moisture and/or prevent its incursion. In one example, a butyl-rubber containing moisture getter or desiccant is used.

In certain embodiments, a sealing sheet that is pierced through with a contact tip has some conductive material embedded within the sheet that is not in an electrical communication with the junction. For example, a pierceable backside sheet may include a metallic layer for improving moisture barrier properties of the sheet. Examples of such backside sheets are described in U.S. patent application Ser. No. 12/556,460 entitled “Isolated Metallic Flexible Back Sheet for Solar Module Encapsulation” filed on Sep. 9, 2009, which is incorporated herein by reference. In certain embodiments, the conductive portion of the contact tip is insulated from conductive materials in the sealing sheet.

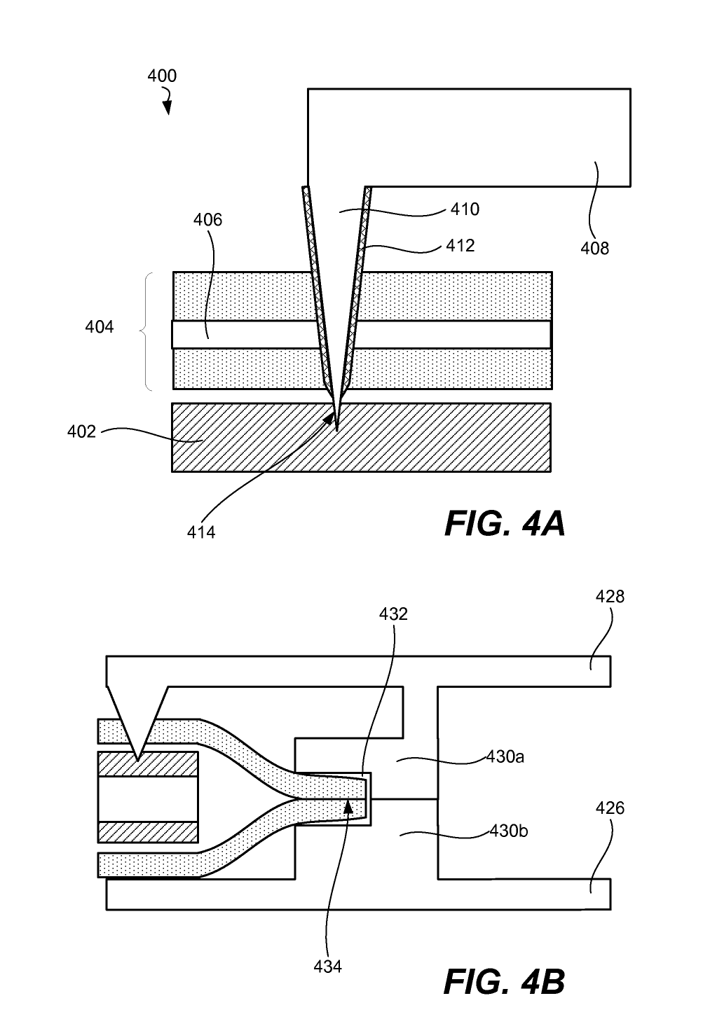

FIG. 4A is a schematic representation of a photovoltaic assembly 400 in which the contact tip 410 of contact arm 408 has an insulating sheath 412 in accordance with certain embodiments. The tip 410 is pierced through a stacked sheet 404 that contains a conductive layer 406. In the installed position shown in FIG. 4, the tip 410 is insulated from the conductive layer 406 of the sealing sheet 404 by the insulating sheath 412. The insulating sheath 412 is positioned over only a portion of the tip 410. A non-insulated portion 414 of the tip 410 contacts and establishes an electrical connection to the contact layer 402.

In various examples described above, a contact tip makes an electrical connection with a contact layer that is on the same side of the junction as the pierced sealing sheet. In other embodiments, a connector having a partially insulated contact tip, similar to one shown in FIG. 4A, can be used to pierce through the semiconductor junction and to form an electrical connection with a contact layer on the other side of the junction.

Conductive portions of the photovoltaic electrical connector that extend outside of the module after installation of the connector are typically insulated. Photovoltaic modules are often installed while their cells are exposed to sun, which results in a voltage applied to the contact layers. The insulated surfaces protect an installer from being exposed to this voltage. In certain embodiments, a module connector is configured to limit an electrical current that can pass through the connector, e.g., by acting as a circuit breaker.

In addition to forming electrical connections with contact layers, module connectors described herein may be used for other purposes. For example, connectors can seal and/or electrically insulate a portion of the edge of the photovoltaic module. In certain embodiments, sets of photovoltaic modules are separated from a photovoltaic roll, as described in U.S. patent application Ser. No. ______, titled “Flexible Photovoltaic Modules in a Continuous Roll” (Attorney Docket MSOLP040, filed concurrently) incorporated herein by reference. These sets may have exposed electrical contacts, for example, formed by the separated electrical connections. A module connector can have a U-shape channel that is configured to snugly fit over edges of the modules in order to provide an additional seal and/or electrical insulation to these edges. An example is shown in FIG. 4B, where contact arm 428 and support arm 426 have L-shaped extensions 430a and 430b that meet to form a U-shaped channel 432 that is configured to fit over a module edge 434. In the depicted embodiment, L-shaped extensions 430a and 430b are positive stop features as well.

### Arrangements of Multiple Connectors on One Module

Photovoltaic modules often have multiple photovoltaic cells interconnected in series. Such modules can deliver electrical power at a voltage that is as high as a sum of operating voltages of all interconnected cells, when the power is drawn from the end cells. When lower voltage levels are needed, a conventional approach is to use DC-DC converter outside of the module. The novel photovoltaic module connectors described herein can be used to make electrical connections to any cell in the module. Because the external connections can be made to any cell in the module and are not limited to the end cells, any desired voltage (in increments of the individual cell voltages) can be drawn by connecting the appropriate cells or, more particularly, the appropriate contact layers of the cells or connected to cells. Voltages as low as an operating voltage of one cell can be drawn.

In certain embodiments, a photovoltaic module connector can be installed at any location along one or more edges of the module. In certain embodiments, the photovoltaic module connector can be installed to electrically connect to either the front (light-facing) or backside of the photovoltaic stack of any cell in the module. For example, a stainless steel substrate can be used as one contact layer, and a wire network positioned over the other side of the semiconductor junction can be used as another contact layer. The wire network may extend outside of the cell's boundaries and make an electrical connection to the stainless steel substrate of the neighboring cell, acting as cell-to-cell interconnect.

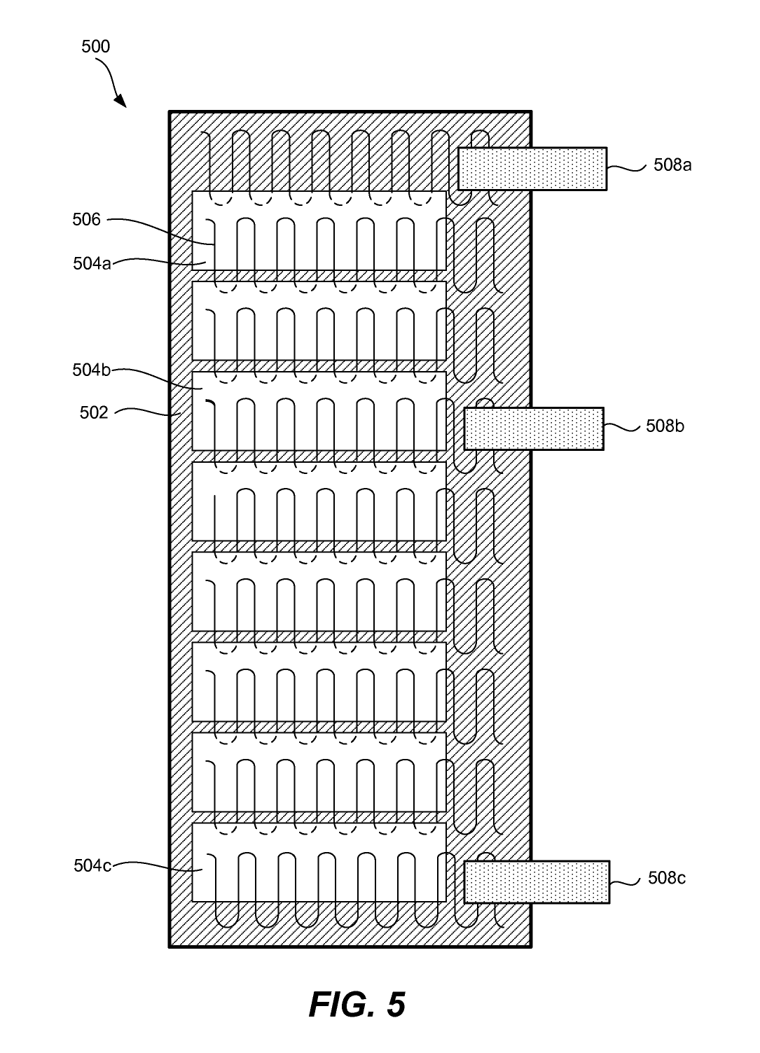

FIG. 5 is a schematic representation of a photovoltaic assembly 500 containing a module 502 and three module connectors 508a, 508b, and 508c installed on the module 502 in accordance with certain embodiments. The module 502 has multiple cells 504 interconnected in series with interconnect wires 506, shown as serpentine shaped wires. Each side of each cell 504 is connected to a separate interconnect wire 506, which interconnect the cells 504. In the depicted embodiment, the interconnect wires 506 also act as current collectors for the front side of the cells 504. The interconnect wires 506 are contact layers, and allow connection to either the front side or backside of a particular cell by connection to the appropriate interconnect wire 506.

As shown in FIG. 5, module connector 508a is electrically connected to the backside of end cell 504a. The two other module connectors 508b and 508c are connected to the front sides the third (504b) and eighth (504c) cells, respectively. In this configuration, an electrical power can be drawn from any pair of the electrical connectors, i.e., 508a and 508b; 508a and 508c; or 508b and 508c. However, the voltage will depend on which pair is selected. The voltage between the connectors 508a and 508b is a combined voltage of the first three cells. The voltage between the connectors 508b and 508c is a combined voltage of the five following cells. Finally, the voltage between the connectors 508a and 508c is a combined voltage of eight cells or a total voltage of the module. While wire interconnects/current collectors are depicted as contact layers in FIG. 5, multiple connectors may be similarly connected to a module via any appropriate contact layers.

Any arrangement of module collectors on a photovoltaic module is possible. For example, the number of cells between each pair of nearest connectors is the same in certain embodiments. In these embodiments, power outputs drawn from these pairs of the connectors are at the same voltage levels. As described, the novel module connectors can provide additional flexibility in designing and installing photovoltaic modules and arrays. For example, these connectors can be used to in conjunction with photovoltaic rolls having variable numbers of modules and/or cells as described in U.S. patent application Ser. No. ______, titled “Flexible Photovoltaic Modules in a Continuous Roll,” (Attorney Docket MSOLP040, filed concurrently), incorporated herein by reference. Modules within these photovoltaic rolls may be separated into different-sized sets, for example, for custom sizing at a particular installation site. The module connectors described herein may be used to connect any desired arrangement of modules and cells within the modules in these sets.

### Installation Process

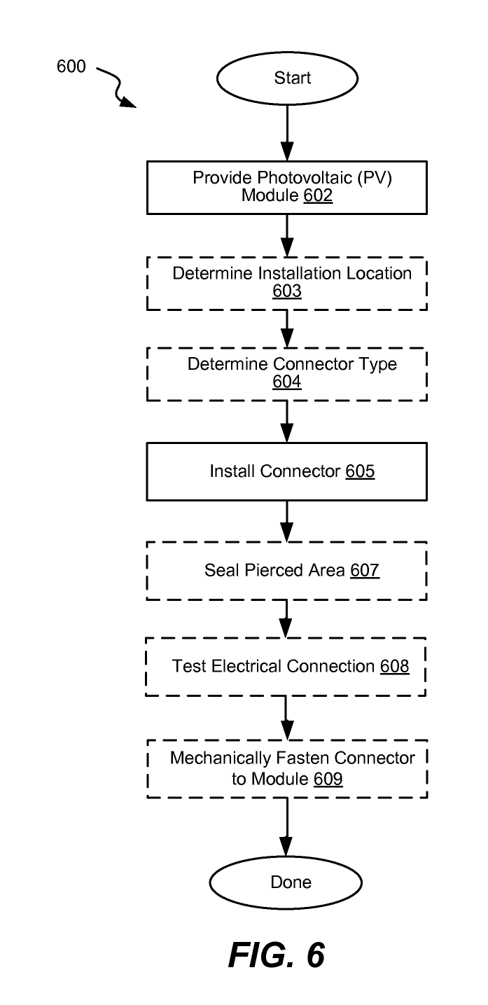

FIG. 6 is a process flowchart of a technique for installing a photovoltaic module connector onto a photovoltaic module in accordance with certain embodiments. The process 600 may start with providing a module or any other photovoltaic structure (e.g., a photovoltaic set) containing one or more photovoltaic modules or cells in operation 602. Various examples of the modules and structures are described above and in U.S. patent application Ser. No. ______, titled “Flexible Photovoltaic Modules in a Continuous Roll (Attorney Docket MSOLP040, filed concurrently), incorporated herein by reference. In certain embodiments, the rolls have at least one sealing sheet that can be pierced through by a contact tip of the electrical connector.

The process 600 may proceed with determining one or more installation locations on a photovoltaic module in operation 603. For example, a connector may be installed to draw an electrical power at a specific voltage as described above in the context of FIG. 5. Additional considerations may include space availability and locations of contact layers (e.g., tabs extending outside of the photovoltaic cell boundaries). In certain embodiments, a module may have specific indications (e.g., markings on the module exterior) of one or more module connector installation areas. In embodiments in which both sheets are pierceable, this operation may also involve determining which of the two sealing sheets should be pierced through with a contact tip of the module connector.

The process 600 may also involve determining a type of connector needed for installation (block 604). Different sheets may require different connector types and/or installation techniques. For example, thinner sheets may need larger positive stops as described above. In certain embodiments, a connector is specifically configured prior to its installation on a module. For example, a connector may be equipped with a specific spacer, seal, and/or spring configured for a specific module and/or pierceable sheet.

The process 600 continues with installing a photovoltaic module connector in operation 605. During this operation, a connector may be aligned with respect to one or more edges of the module. Other features of the module may also be used for this alignment. For example, one sheet of the module is generally transparent and allows an installer to see various elements inside the module (e.g., photovoltaic cells). The installer may therefore visually align with the connector with respect to one or more cells or other elements of inside the module. The installer may visually align the connector to a marking on the outside of the module.

The process 600 may involve other operations, such as sealing the pierced area (block 607), testing established electrical connections (block 608), and mechanically fastening the connector to the module after the connection is made (block 609). For example, an installer may provide a sealing and/or adhesive material before, during, and/or after installation of the module connector. Testing the established connections may involve, for example, measuring an electrical resistance between two installed connectors. It should be noted that this resistance measurement technique can be continuously performed during advancement of the contact tip into the module to control the position of the tip. Mechanically fastening may involve using a clip, spring or other fastener to hold the connector in place. After installation, the connector may be connected to another module, a grid or other external connection point.

### Connecting Arrays

Electrical connectors and techniques described above can be used for establishing electrical connections to modules that form photovoltaic arrays. FIG. 7 is a schematic representation of a photovoltaic array 702 that includes twenty one photovoltaic modules 703 and seven electrical connectors 708a-708g in accordance with certain embodiments. The array 702 provides an electrical power to a device 704, which may be an electrical grid, battery, or any other device that consumes electrical power.

As shown in FIG. 7, the modules 703 are arranged into three different sets 706a-706c. This arrangement may be dictated by various installation requirements (e.g., obstacles in the installation area). In certain embodiments, the modules 703 are provided in a photovoltaic roll described above. As shown, each of the three sets 706a-706c has a different number of the modules. The electrical connectors 708a-708g connect (directly or indirectly) all modules to the device 704 irrespective of the set sizes. While the description below assumes modules 703 are interconnected in series in their respective sets, one skilled in the art would readily recognize that these connectors can also be used for sets of modules interconnected in series, in parallel, various combinations of series and parallel connections, or not interconnected at all.

The six modules in the set 706b are connected to the device 704 using two electrical connectors, 708f and 708g. Similarly, three modules of set 706c are connected to device 704 using two connectors 708d and 708e. It should be noted that two or more connectors can share the same electrical wiring to the device 704, e.g., as connectors 708e and 708f do in FIG. 7. Furthermore, it should be noted that some connectors (e.g., connector 708d in FIG. 7) may not be directly connected to the device 704.

A larger set 706a has twelve modules. If twelve modules connected in series provide higher current than can be handled by various interconnecting elements, then this set should be electrically separated into two subsets. In FIG. 7 the connector 708b is used to create a subset of eight modules that is electrically disconnected from (i.e., not connected in series with) the remaining four modules of the set 706a. It should be noted that all modules of the set 706a may remain mechanically integrated, e.g., by keeping all modules mechanically attached to each other and sealed under the same continuous sealing sheets.

The connector 708b is installed in between two subsets (one having four modules and one having eight modules) of the set 706a. The connectors 708a and 708b are used to connect the eight module subset to the device 704. Furthermore, the connectors 708b and 708e are used to connect the four module subset together with the set 706c to the device 704. The four modules and the set 706c can be interconnected in parallel with the connectors 708c and 708d. FIG. 7 provides an example of a possible arrangement of modules in an array. This example further illustrates the flexibility of electrical connections described above that the novel connectors provide in the context of array installation. One of skill in the art will understand how to connect one or more modules in any desired arrangement using the module connectors based on the above description.

### Conclusion

Although the foregoing invention has been described in some detail for purposes of clarity of understanding, it will be apparent that certain changes and modifications may be practiced within the scope of the appended claims. It should be noted that there are many alternative ways of implementing the processes, systems and apparatus of the present invention. Accordingly, the present embodiments are to be considered as illustrative and not restrictive, and the invention is not to be limited to the details given herein.

What is claimed is:

1. A photovoltaic assembly comprising:
a photovoltaic module comprising a semiconductor junction sealed between a first sheet and a second sheet, said first sheet comprising a pierceable material and a contact layer; and
a photovoltaic module electrical connector comprising:
a contact arm having a conductive contact tip for penetrating the first sheet of the module to contact the contact layer;
a support arm forming a variable gap with the contact tip; and
an insulator surrounding at least a portion of the contact arm and/or the support arm and providing an electrical insulation to said portion of the contact arm and/or the support arm,
wherein the support arm and the contact arm are configured to maintain the variable gap such that the contact tip maintains an electrical contact to the contact layer but does not penetrate completely through the contact layer.

2. The photovoltaic assembly of claim 1, wherein the photovoltaic module electrical connector further comprises a positive stop configured to maintain the variable gap such that the contact tip maintains the electrical contact to the contact layer but does not penetrate completely through the contact layer.

3. The photovoltaic assembly of claim 2, wherein the positive stop is provided by a direct contact between the contact arm and the support arm.

4. The photovoltaic assembly of claim 2, wherein the positive stop comprises a surface contacting the first sheet of the photovoltaic module, and wherein the contact tip extends from said surface by a predetermined distance.

5. The photovoltaic assembly of claim I, wherein the variable gap is maintained at a distance sufficiently large to accommodate at least the semiconductor junction and the second sheet without causing an electrical short to the semiconductor junction.

6. The photovoltaic assembly of claim 1, wherein a set force maintains the variable gap such that the contact tip maintains the electrical contact to the contact layer but does not penetrate completely through the contact layer.

7. The photovoltaic assembly of claim 6, wherein the set force is controlled by a mechanical spring provided between the contact arm and the support arm.

8. The photovoltaic assembly of claim 6, wherein the set force is adjustable.

9. The photovoltaic assembly of claim 1, wherein the photovoltaic module comprises a reinforcement strip positioned between the semiconductor junction and the contact tip.

10. The photovoltaic assembly of claim 1, wherein the contact tip is bent relative to a penetration direction.

11. The photovoltaic assembly of claim 1, wherein the contact tip partially penetrates the contact layer without causing an electrical short in the semiconductor junction.

12. The photovoltaic assembly of claim 1, wherein the contact tip is sufficiently conductive to transmit an electrical current provided by at least five photovoltaic modules interconnected in parallel.

13. The photovoltaic assembly of claim 1, wherein the photovoltaic module electrical connector comprises a plurality of contact tips.

14. The photovoltaic assembly of claim 1, wherein the first sheet has an average thickness between about 5 mils and 100 mils.

15. The photovoltaic assembly of claim 1, wherein the first sheet is a backside sheet comprising a metallic vapor barrier and wherein the contact tip comprises an insulating sheath covering a portion of side walls of the contact tip and insulating the contact tip from the metallic vapor barrier.

16. The photovoltaic assembly of claim 1, wherein the contact layer comprises one or more elements selected from the group consisting of:
a metallic substrate used for mechanical support of the semiconductor junction,
a set of metallic current-collector wires positioned over a frontside of the semiconductor junction, and
a tab extending laterally outside of the semiconductor junction.

17. The photovoltaic assembly of claim 1, wherein the contact tip is self-sealing such that when penetrating the first sheet, the contact tip seals the photovoltaic module from an external environment in a penetration area.

18. The photovoltaic assembly of claim 1, the photovoltaic module electrical connector further comprises a sealing material compressed between the contact arm and the first sheet.

19. The photovoltaic assembly of claim 1, the photovoltaic assembly is configured such that the photovoltaic module electrical connector can be installed at any location along an edge of the photovoltaic module.

20. The photovoltaic assembly of claim 1, wherein the contact tip comprises retaining features configured to maintain the electrical contact between the conductive contact tip and the contact layer.

21. The photovoltaic assembly of claim 1, further comprising:
a second photovoltaic module electrical connector for connecting to a second photovoltaic cell of the photovoltaic module; and
a third photovoltaic module electrical connector for connecting to a third photovoltaic cell of the photovoltaic module,
wherein a first photovoltaic cell comprising the semiconductor junction, the second photovoltaic cell, and the third photovoltaic cell electrically interconnected in series and connected to the photovoltaic module electrical connector, the second photovoltaic module electrical connector, and the third photovoltaic module electrical connector, respectively, and
wherein a voltage between the first connector and the second connector and a voltage between the second connector and the third connector are substantially the same.

22. A photovoltaic module electrical connector for connecting to a photovoltaic cell of a sealed photovoltaic module, said photovoltaic cell having a contact layer, and for transmitting electrical current to or from the contact layer, the photovoltaic module electrical connector comprising:
a contact arm having a conductive contact tip for penetrating a penetrable frontside or backside sheet of the module to contact the contact layer;
a support arm forming a variable gap with the contact tip; and
an insulator surrounding at least a portion of the contact arm and/or the support arm and providing electrical insulation to said portion of the contact arm and/or the support arm,
wherein the support arm and the contact arm are configured to maintain the variable gap such that the contact tip maintains electrical contact to the contact layer but does not penetrate through the contact layer.

23. A photovoltaic array comprising:
at least one photovoltaic module including a plurality of interconnected photovoltaic cells sealed within an exterior;
at least two external connectors electrically connected to different cells of the plurality of photovoltaic cells;
wherein the at least two external connector comprise conductive contact tips pierced through the exterior of the at least one photovoltaic module.
